(19) United States
(12) Patent Application Publication
(10) Pub. No.: US 2018/0159063 A1
(43) Pub. Date: Jun. 7, 2018

(54) Organic Heterocyclic Alkali Metal Salts As N-Dopants In Organic Electronics

(71) Applicant: Siemens Aktiengesellschaft, Muenchen (DE)

(72) Inventors: Florian Kessler, Wachenroth (DE); Sebastien Pecqueur, La Couture (FR); Guenter Schmid, Hemhofen (DE)

(73) Assignee: Siemens Aktiengesellschaft, Muenchen (DE)

(21) Appl. No.: 15/579,263

(22) PCT Filed: Apr. 26, 2016
(86) PCT No.: PCT/EP2016/059229

§ 371 Date: Dec. 4, 2017

(30) Foreign Application Priority Data
Jun. 5, 2015 (DE) 102015210388.9

(51) Int. Cl. H01L 51/50; H01L 51/00; C09K 11/06

(52) U.S. Cl. CPC H01L 51/5076; C09K 2211/1044; C09K 11/06; H01L 51/0067

(57) ABSTRACT

N-dopants for increasing the electronic conductivity of organic electrical layers. The n-dopants may be processed, especially sublimed, in a simple and/or inexpensive manner which may additionally lead to distinctly elevated electronic conductivity of organic electron transport layers. The n-dopants comprise heterocyclic alkali metal salts.

### CROSS-REFERENCE TO RELATED APPLICATIONS

This application is a U.S. National Stage Application of International Application No. PCT/EP2016/059229 filed Apr. 26, 2016, which designates the United States of America, and claims priority to DE Application No. 10 2015 210 388.9 filed Jun. 5, 2015, the contents of which are hereby incorporated by reference in their entirety.

### FIELD OF THE INVENTION

The present invention relates to n-dopants for increasing the electronic conductivity of organic electrical layers, wherein the n-dopant is selected from the group comprising heterocyclic alkali metal salts of the following formula I

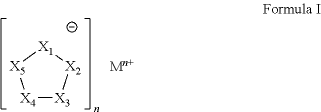

wherein
X₁-X₅ are independently selected from the group comprising —CH₂—, —CHR—, —CR₂—, —C(═O)—, —(C═S)—, —(C═CR₂)—, —C(CR)—, ═CH—, ═CR—, —NH—, —NR—, ═N—, —O—, —S—, —Se—, —P(H)—, —P(R)—, —N⁻—, ═C⁻—, —CH⁻—, —CR⁻—, —P⁻—, where at least one Xᵢ provides a heteroatom in the five-membered ring and the ring has a formal negative charge; R is independently selected from the group comprising —H, -D, halogen, —CN, —NO₂, —OH, amine, ether, thioether, ester, amide, C1-C50 alkyl, cycloalkyl, acryloyl, vinyl, allyl, aromatics, fused aromatics, heteroaromatics; M=alkali metal or alkaline earth metal and n=1 or 2.

### BACKGROUND OF THE INVENTION

Functional electron transport layers for components in organic electronics can in principle be obtained by different production methods. The first, simplest variant is by deposition of materials having high electron mobility within a layer on a carrier material. In this case, it is the electron mobility and the number of mobile/free charge carriers in the deposited material that determine the transportability (conductivity) and the injection properties of the layer. However, these layers generally do not meet current demands on high-functionality components and, secondly, more complex processes have accordingly been created in order to further improve the transport and injection properties. These processes essentially include the insertion of thin salt interlayers, for example composed of LiF, CsF or Cs₂CO₃ (Jinsong Huang et al. “Low-Work-Function Surface Formed by Solution-Processed and Thermally Deposited Nanoscale Layers of Cesium Carbonate”, Adv. Funct. Mater. 2007, 00, 1-8), between cathode and electron transport layer (electron injection layer) or the doping of the electron transport layer itself (bulk doping). The thin salt layers form an interface layer with the cathode material and lower the work function of the electrons. The interfacial resistance between metal electrode and organic layer is significantly improved as a result, but this improvement is still inadequate for high-efficiency organic light-emitting diodes. In a doping operation, further substances are not introduced in separate layers, but together with the electron conductor within a layer. This direct doping of the electron conductors can likewise be effected, for example, with Cs₂CO₃ (G. Schmid et al., “Structure Property Relationship of Salt-based n-Dopants in Organic Light Emitting Diodes”, Organic Electronic Conference 2007, Sep. 24-26, 2007, Frankfurt, Germany) and results in an increase in the n-conductivity of the layer.

For practical producibility, the selection of dopants, however, has to meet a wide variety of different demands. In electronic terms, in general, the HOMO (highest occupied molecular orbital) of the dopant should be above (closer to the vacuum level) of the LUMO (lowest unoccupied molecular orbital) of the matrix material (electron conductor). Only in this way can an electron be transferred from the dopant to the matrix and the conductivity thereof increased as a result. This can be achieved, for example, by means of materials having extremely low work functions or ionization energies (alkali metals and alkaline earth metals, and the lanthanoids). However, there is also a newer model for the doping of organic semiconductors in which an intermolecular complex (called a charge transfer complex) forms and hence, doping is also possible when the above-described situation (HOMO of the dopant higher than the LUMO of the matrix) does not exist (H. Méndez et al., Angew. Chem. Int. Ed. 2013, 52, 1).

In addition, however, the dopants also have to be processable by the standard operations in organic electronics. This includes good solubility in the solvents commonly used in wet processing and/or, especially in the case of vacuum processes, easy evaporability of the compounds. In this way, the energy input for production of the layers can be reduced. The latter prerequisite is only satisfied to a degree in the case of inorganic, salt-type dopants, for example cesium phosphate (described, for example, in WO 2011/039323 A2) or phosphorus oxo salts (described, for example, in DE102012217574 A1), for n-doping, since the sublimation temperatures of these compounds are relatively high. The use of organic salts, for example, the salts of cyclopentadiene (described in DE1020 12217587 A1) can contribute to improved processability; there is nevertheless still a need for efficient n-dopants that have not only good processability, here low sublimation temperatures in particular, but additionally suitable electronic properties that lead to a distinct improvement in the electrical conductivity of organic electrical layers.

### SUMMARY OF THE PREFERRED EMBODIMENTS OF THE INVENTION

It is therefore an object of the present invention to provide n-dopants which can be processed, especially sublimed, in a simple and inexpensive manner and which additionally lead to distinctly elevated electronic conductivity of organic electron transport layers.

According an embodiment of the invention, an n-dopant for increasing the electrical conductivity of organic electrical layers is used, which is characterized in that the n-dopant is selected from the group comprising heterocyclic alkali metal salts of the following formula I

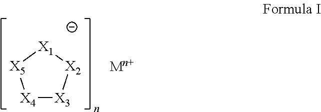

wherein
X₁-X₅ are independently selected from the group comprising —CH₂—, —CHR—, —CR₂—, —C(═O)—, —(C═S)—, —(C═CR₂)—, —C(CR)—, ═CH—, ═CR—, —NH—, —NR—, ═N—, —O—, —S—, —Se—, —P(H)—, —P(R)—, —N⁻—, ═C⁻—, —CH⁻—, —CR⁻—, —P⁻—, where at least one Xᵢ provides a heteroatom in the five-membered ring and the ring has a formal negative charge; R is independently selected from the group comprising —H, -D, halogen, —CN, —NO₂, —OH, amine, ether, thioether, ester, amide, C1-C50 alkyl, cycloalkyl, acryloyl, vinyl, allyl, aromatics, fused aromatics, heteroaromatics;
M=alkali metal or alkaline earth metal and
n=1 or 2. It has been found that, surprisingly, these salt-type compounds have suitable electronic properties to dope the electron transport materials commonly used in organic electronics and hence to contribute to elevated conductivity of layers produced therefrom. Without being bound by theory, this effect is very probably a result of the HOMO/LUMO position of the salt-type compounds usable in accordance with embodiments of the invention compared to the electrode material or matrix material and is especially based on the presence of a heteroatom in the organic cycle. The particular effect of this heteroatom in the cyclic compound seems to be that the anion may release an electron more easily to the surrounding matrix material, which leads to an increase in the conductivity of this material. Without being bound by theory, the easier release very probably results from the fact that, by comparison with pure cyclic compounds, there is a more marked tendency to release of the negative charge to electron transport materials in heterocycles. As already stated above, this may be because of the HOMO/LUMO position of the heterocyclic anion, which is more favorable than, for example, the electronic levels of the pure aliphatic cyclic compounds. Moreover, the dopants of the invention show good solubility in the solvents commonly used in organic electronics, which contributes to good wet processability of these compounds. However, a particular advantage of this class of compounds also arises from the fact that they can be evaporated at much lower temperatures compared to the salt-type compounds used in the prior art. For example, sublimation temperatures below 600° C. can be achieved. Without being bound by theory, this probably results from the specific choice of the organic anions which lead to a distinct reduction in the sublimation temperatures. Thus, dopants having both suitable electronic and desirable processing-related properties are obtained. This may lead to a reduction in the production costs. As well as the electronic properties, the compounds usable in accordance with embodiments of the invention may also have a good interaction with the electron transport materials. This may be manifested in rapid reaction kinetics and in a firm attachment, especially of the anion to the electron conductor. This was unforeseeable since the steric prerequisites of organic anions, because of their spatial extent, are actually less favorable than the inorganic salts used in the prior art (and here especially those of the inorganic anions). One possible mechanism for increasing the electrical conductivity of the electron conductors arises, for example, through the following equilibrium:

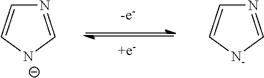

The heterocyclic 5-membered ring can form either a resonance-stabilized anion or a resonance-stabilized free-radical via acceptance or release of an electron. In the case that the electron is released, it is accepted by the electron transport material.

Advantageously, it is additionally found that electron-conducting matrix materials are simultaneously good aromatic complexing agents for the metal cations usable in accordance with embodiments of the invention. This may result in complex formation between the metal cations and the matrix materials, which may lead to particularly stable layers. This stability of the layers may simplify processability. For example, in solvent processes, it is possible to continue operation with a distinctly higher number of non-complementary solvents without any risk that the n-dopants of the invention will be washed out. Examples of chelating electron-conducting matrix materials of this kind include 2,9-dimethyl-4,7-diphenyl-1,10-phenanthroline (BCP) or 4,7-diphenyl-1,10-phenanthroline (BPhen), which may be used with preference. The resulting coordination number of the metal atom may vary between 2-8 according to the atomic radius of the metal used (for example Li: 4, Cs: 6-8). The dopant may, in a formal sense, be in the form of an ion pair in the matrix or be fully ionized by the dissolving matrix.

A model representation of the n-dopant dissolved in a matrix of electron conductors is shown below:

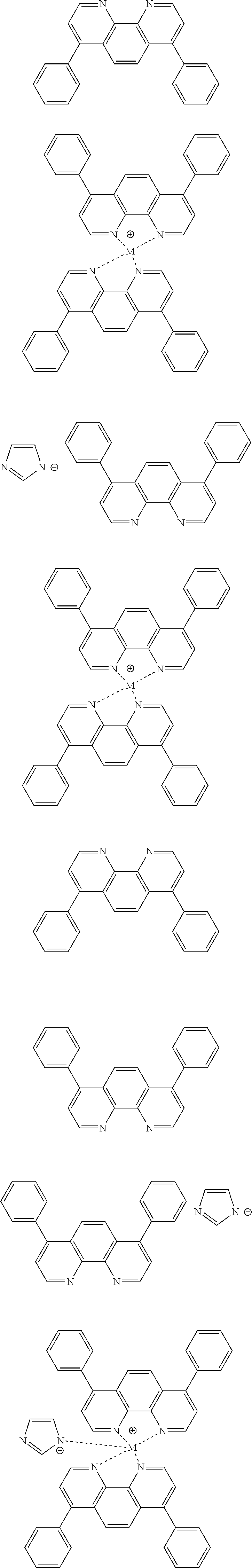

An n-dopant in the context of the invention is a compound in salt form, e.g., a compound formed from organic anions and inorganic cations, wherein the anion may release an electron, or electron density in a quite general sense, to surrounding electron conductors. By virtue of this mechanism, the n-dopants of embodiments of the invention may contribute to an increase in the electron density in organic electronic layers. The organic compound here may form the anion of the complex and may have a formal single negative charge. This simultaneously means that just one of the Xᵢ (i=1-5) groups formally characterized as charge-bearing, for example —N⁻—, may occur in the ring. This charge may, of course, be delocalized over the entire ring and, given suitable electronic structure, also over the radicals bonded thereto. To compensate for the charge of the complex, 1:1 complexes form with alkali metal cations, and 2:1 complexes with alkaline earth metal cations. The 5-membered heterocyclic ring complexes of embodiments of the invention may either be processed directly or else be prepared in a solid phase synthesis by co-condensation of the alkali metal/alkaline earth metal and a deprotonatable 5-membered heterocyclic ring. Within this preferred embodiment, the metal, the uncharged heterocycle and the matrix material may thus be deposited together within a layer and the metal-heterocycle complex of some embodiments of the invention does not form until within the layer, for instance via elimination of an acidic proton by the following mechanism:

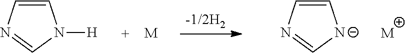

It is thus not absolutely necessary for an ionic compound to be used as reactant. In addition, the groups for Xᵢ and for R may not only comprise the members listed, but also consist of these members.

Heterocyclic alkali metal/alkaline earth metal salts in the context of the invention may be organic salts, wherein the anion has a 5-membered heterocyclic structure as the base skeleton. This 5-membered structure may have at least one heteroatom from the group specified in the base skeleton. Alternatively, it is possible that 2-4 atoms of the base skeleton provide a heteroatom. Accordingly, the heterocycle in that case may have multiple heteroatoms, in which case it is also possible that different heteroatoms may be present in the ring. Irrespective of whether the 5-membered ring has one or more heteroatoms, the 5-membered ring may always bear at least one negative charge. Useful metals include the metals familiar to the person skilled in the art from the alkali metal and alkaline earth metal group. In other words, the cations are chosen from the group consisting of Li, Na, K, Rb, Cs, Be, Mg, Ca, Sr, and Ba. The person skilled in the art will be aware that, according to the charge of the metallic cation, one or 2 organic anions may be required to compensate for the charge of the complex.

Examples of heterocyclic five-membered rings usable in accordance with the invention are:

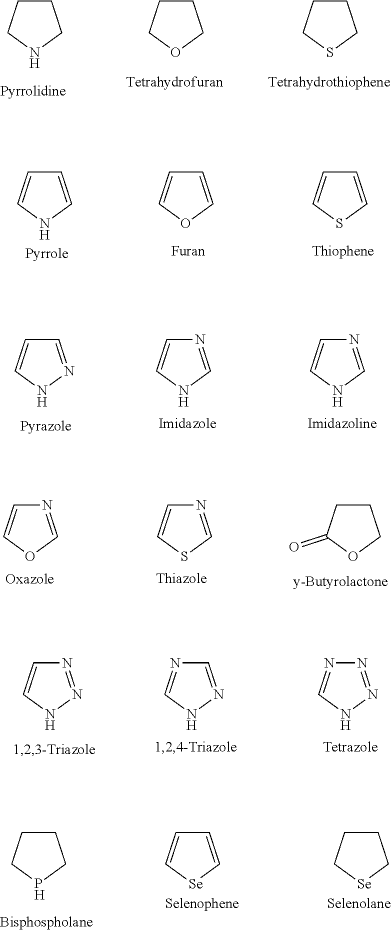

wherein these base skeletons may be substituted at any other site capable of bonding.

The n-dopants of some embodiments of the invention may be capable of increasing the conductivity of organic electrical layers. The person skilled in the art is aware of the materials of which the organic electrical layers may consist. For example, the n-dopants of some embodiments of the invention may be suitable for use together with one or more of the following n-conductors: 2,2′,2″-(1,3,5-benzenetriyl)-tris(1-phenyl-1H-benzimidazole); 2-(4-biphenylyl)-5-(4-tert-butylphenyl)-1,3,4-oxadiazole; 2,9-dimethyl-4,7-diphenyl-1,10-phenanthroline (BCP); 8-hydroxyquinolinolatolithium; 4-(naphthalen-1-yl)-3,5-diphenyl-4H-1,2,4-triazole; 1,3-bis[2-(2,2′-bipyridin-6-yl)-1,3,4-oxadiazol-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazol-2-yl]-2,2′-bipyridyl; 2-phenyl-9,10-di(naphthalen-2-yl)anthracene; 2,7-bis[2-(2,2′-bipyridin-6-yl)-1,3,4-oxadiazol-5-yl]-9,9-dimethylfluorene; 1,3-bis[2-(4-tert-butylphenyl)-1,3,4-oxadiazol-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyl-dipyrenylphosphine oxide; naphthalenetetracarboxylic dianhydride or imides thereof; perylentetracarboxylic dianhydride or imides thereof; 2,3,5,6-tetrafluoro-7,7,8,8-tetracyanoquinodimethane; pyrazino[2,3-f][1,10]phenanthroline-2,3-dicarbonitrile; and dipyrazino[2,3-f:2′,3′-h]quinoxaline-2,3,6,7,10,11-hexacarbonitrile. Further usable electron transport materials are, for example, those based on siloles with a silacyclopentadiene unit or heterocycles as described in EP 2 092 041 B1.

In a further embodiment of the invention, the n-dopants of the invention may also be deposited within a layer together with hole-conducting materials and hence, form a blocking layer.

In a preferred embodiment of the invention, the at least one heteroatom in the five-membered ring may be a nitrogen. Especially the heterocycles in which at least one nitrogen atom is present may lead to particularly effective doping of electron transport materials. Without being bound by theory, this effect may be attributable to the fact that both the electronic structure of the five-membered ring and the stability of the anions are favorably affected by the presence of at least one nitrogen atom. This can possibly be attributed to the options for resonance stabilization of the anion by the nitrogen atom and, in general, the electronegativity thereof compared to carbon.

In a further embodiment of the invention, there may especially be at least two nitrogen atoms in the five-membered ring of the n-dopants. More particularly, heterocyclic 5-membered rings having at least 2 nitrogen atoms in the ring system have also been found to be suitable. Without being bound by theory, this may be explained by the improved resonance stabilization of the anions formed and generally by the elevated electron density provided by the free electron pairs of the nitrogen atoms. Particularly preferred configurations of these specific 5-membered rings may be selected from the group comprising imidazole and imidazoline, e.g., five-membered rings having nitrogen atoms in 1 and 3 positions.

In a further embodiment of the invention, the metal M may be selected from the group comprising Li, Na, K, Rb and Cs. Particularly, the group of the monovalent alkali metals has been found to be particularly suitable in the context of the processing. This processing is preferably within vacuum operations, since the complexes of the alkali metals and the 5-membered heterocyclic rings appear to have particularly good evaporability at low temperatures. This may possibly be attributed to the fact that only 1 to 1 complexes have to be evaporated. This may lead to enhanced process economics.

In a preferred embodiment, the metal may be Rb or Cs. The heavy alkali metals may be deposited very efficiently within the context of vacuum processes together with the heterocycles usable in accordance with some embodiments of the invention and form particularly stable layers with the electron transport materials. This is very probably based on the greater ionic radius of the cations, which enables effective interaction with multiple molecules of the electron transport material. In this manner, layers which have been found to be particularly resistant to the washout of the dopants introduced in subsequent operating steps are obtainable.

Moreover, in an additional embodiment of the invention, the metal may be Cs. Cesium, being the heaviest non-radioactive material from the group of the alkali metals, surprisingly leads to a particularly efficient and rapid reaction with the electron transport materials. Without being bound by theory, this is very probably a result of the size of cesium, which also enables interactions with multiple molecules of the electron transport material in the electrical layer. This may result in particularly rapid and complete dissociation of the n-dopants of the invention within the matrix material, which then subsequently leads to particularly efficient transfer of charge from the now isolated organic anions to the matrix material.

In a further preferred embodiment, the n-dopant may have a molecular weight of ≥65 g/mol and ≤2000 g/mol. Within the scope of an economic process regime with low process energies, the n-dopants having a comparatively low molecular weight have been found to be particularly efficient means of increasing the electrical conductivity of electron transport materials. First, without being bound by theory, this may be attributable to the fact that these complexes, as a result of their very low sublimation temperature, may be evaporated and deposited particularly efficiently. This contrasts with compounds of higher molecular weight, which may require the use of distinctly higher temperatures in vacuum processes, since these compounds enable only inadequate interaction with the matrix materials. In a further embodiment of the invention, these n-dopants may have a molecular weight of ≥75 g/mol and ≤1500 g/mol, additionally of ≥100 g/mol and ≤1000 g/mol.

Embodiments of the invention further provide an organic electron-conducting layer comprising at least one electron transport material and an n-dopant, wherein the n-dopant comprises one of the compounds of the invention.

The electron-conducting layers doped in accordance with some embodiments of the invention may include either one or more than one of the n-dopants of the invention. The electron-conducting layers doped in accordance with the invention may of course also include multiple matrix materials/electron conductors. As well as these obligatory layer constituents, it is also possible for further substances to be present within the layer. Further utilizable layer materials such as further matrix materials and/or insulators for adjusting the conductivity are known to those skilled in the art.

In an additional embodiment of the invention, the n-dopant may be present in the organic electrical layer in a layer thickness concentration of ≥0.01% and ≤35%. The layer thickness concentration describes the proportion by volume of the salt-type derivative in the overall electron-conducting layer. In the case of vacuum processing, the layer thickness proportions are controlled by means of quartz sensors. For this purpose, first, a pure layer of the materials is evaporated, the real layer thickness is measured and then a correction factor (tooling factor) is determined. The tooling factors for the various substances (dopant+matrix) and the appropriate number of crystal oscillators (sensors) may be used to control the desired layer thickness concentration. This proportion may be calculated, for example, on the basis of the cation distribution within the layer, which is determined, for example, by means of energy-dispersive x-ray structure analysis (EDX) or AAS (atomic absorption spectroscopy). The above-specified layer thickness concentration has been found to be particularly suitable in order to induce a distinct rise in the electrical conductivity of the electron transport materials. Higher layer thickness concentrations may be disadvantageous since the proportion of the electron transport materials in this case will be too low. Lower layer thickness concentrations, by contrast, may lead to only inadequate doping of the electron transport layer. In the case of using 2 or more of the n-dopants of the invention, the above-specified layer thickness concentration applies to the sum total of the dopants used.

In a preferred embodiment of the layer, the n-dopant may be present in the organic electrical layer in a layer thickness concentration of ≥70% and ≤100%. High concentrations of the n-dopant within a layer may preferably be used to construct an electron injection layer (contact doping). This intrinsic layer of the n-dopant is appropriately arranged between the electron transport layer and the cathode and leads to improved injection. In a further preferred embodiment, both the intrinsic layer having high concentrations of the n-dopants of the invention and the electron transport layer may comprise solely the n-dopants of the invention.

Embodiments of the invention may also include a process wherein an n-dopant of the invention is deposited within a layer together with at least one electron transport material. It is possible here for the compounds to be processed either from the gas phase or from the liquid phase. In the case of gas phase deposition, both the dopant and the matrix material may be evaporated under high vacuum together, preferably from different sources, and deposited as a layer. In the case of processing from the liquid phase, the organic dopant and the matrix material may be dissolved together or separately in a solvent and deposited by means of printing techniques, spin-coating, bar-coating, slot-coating, etc. The finished layer is then obtained by evaporating the solvent. It is possible here to establish any desired doping ratios via the different mass ratios of n-dopants to the electron transport material. The use of the n-dopants of some embodiments of the invention may result in both simplification of the production of the layers and in a particularly good electronic conductivity of the layers.

In a further embodiment of the process, the deposition may be effected via a solvent process or a sublimation process. More preferably, the electron-conducting region is produced by means of gas phase deposition, more preferably by means of physical gas phase deposition (PVD). In this step, the dopant may preferably be deposited together with the electron-conducting layer. In principle, however, it is also possible to sequentially deposit the dopant and the matrix material in thin successive layers, for example by means of linear sources. These layers may have a layer thickness of 1-10 nm, preferably <1 nm. Both substances may be sublimed from different sources using thermal energy. By means of this process, particularly homogeneous and uniform layers may be obtained. Solvent processes may preferably be conducted in such a way that the components of the electron-conducting layer and the dopant are deposited onto a substrate from a solvent. This may simplify the process regime and enable more favorable production.

In a further embodiment of the process, the n-dopant may be deposited within a layer without an electron transport material.

In this way, it may be possible to obtain intrinsic contact doping layers having high proportions of n-dopants, the contact of this layer with the metal cathode may result in a decrease in the work function of the electrons and hence, an improvement in the electron injection into the electron transport layer.

A further inventive embodiment of the process comprises deposition by means of a sublimation process with a sublimation temperature of about ≥120° C. and about ≤600° C. and at a pressure of about 1*10⁻⁵ to about 1*10⁻⁹ mbar. In the context of the processing, it has been found that the compounds of the invention having sublimation temperatures between not less than about 120° C. and not more than about 600° C. may be deposited particularly homogeneously from the gas phase. In addition, it is found that a high degree of flexibility with regard to the production equipment may be achieved. The molecular weights of the compounds can easily be calculated from the empirical formulae and the sublimation temperatures are determined by the methods known in the prior art.

Embodiments of the invention may also include an organic electrical component, wherein the component comprises an n-conducting organic electrical layer of the invention. The use of the n-dopants of the invention may lead to improved electrically conducting layers which may be especially suitable for use in organic electrical components in the context of multilayer constructions. The increase in the electrical efficiency and in the lifetime of the layers may thus afford components having a higher quality.

In an additional embodiment of the invention, the organic electrical component may be selected from the group comprising organic photodiodes, solar cells, bipolar and field-effect transistors, and organic light-emitting diodes. As a result of the improved electrical properties of the electrical transport layer of some embodiments of the invention, these layers may be particularly suitable for construction of the above mentioned organic electrical components. It is especially possible here to obtain components having improved electronic properties and also improved service lives.

With regard to further advantages and features of some embodiments of the inventive process described above, reference is hereby made explicitly to the elucidations in connection with the n-dopant of the invention, the layers of the invention and the components of the invention. Features of the invention and advantages of the n-dopants of the invention shall also be considered to be disclosed in respect of the layers of the invention, the process of the invention and the organic components of the invention, and vice versa.

The properties of the layers doped in accordance with certain embodiments of the invention may be elucidated in detail hereinafter with reference to figures. The figures show:

FIG. 1 the IV characteristic of a pure SMB-013 layer (Merck) and of an SMB-013 layer doped with 10% cesium imidazolide (dotted) (% figures as % layer thickness), measured with a calcium cathode;

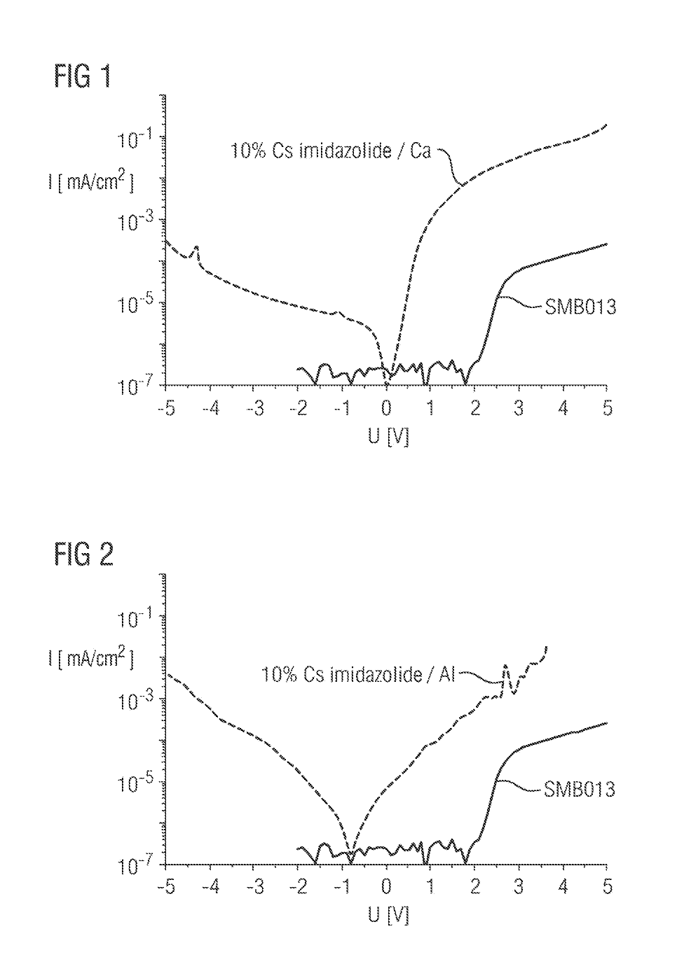

FIG. 2 the IV characteristic of a pure SMB-013 layer (Merck) and of an SMB-013 layer doped with 10% cesium imidazolide (dotted), measured with an aluminum cathode;

FIG. 3 the IV characteristic of a pure Alq₃ layer (tris(8-hydroxyquinoline)aluminum) and of an Alq₃ layer doped with 5% cesium imidazolide (dotted), measured with a calcium cathode;

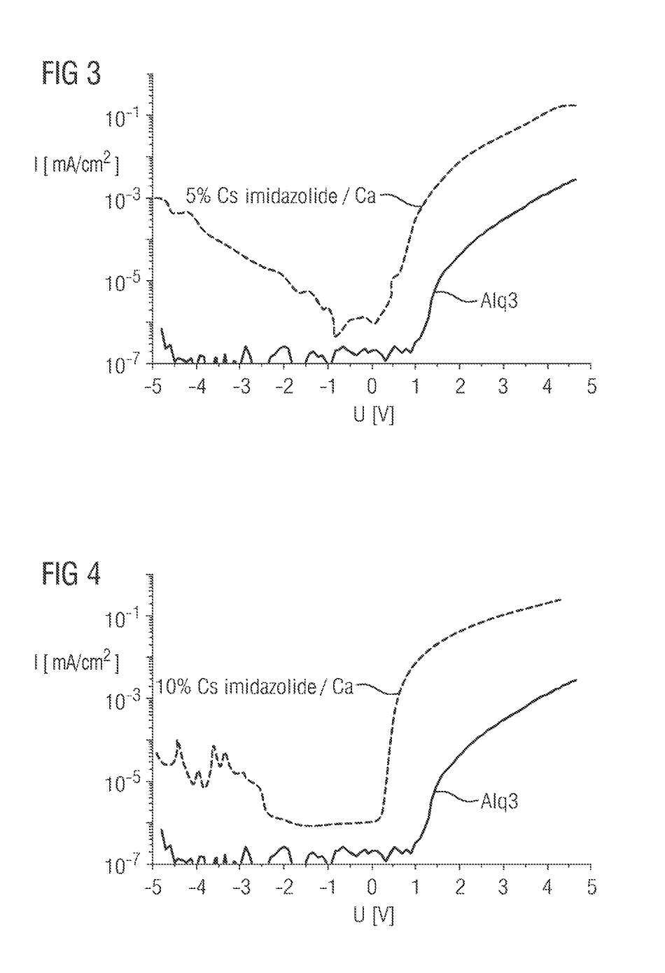

FIG. 4 the IV characteristic of a pure Alq₃ layer (tris(8-hydroxyquinoline)aluminum) and of an Alq₃ layer doped with 10% cesium imidazolide (dotted), measured with a calcium cathode;

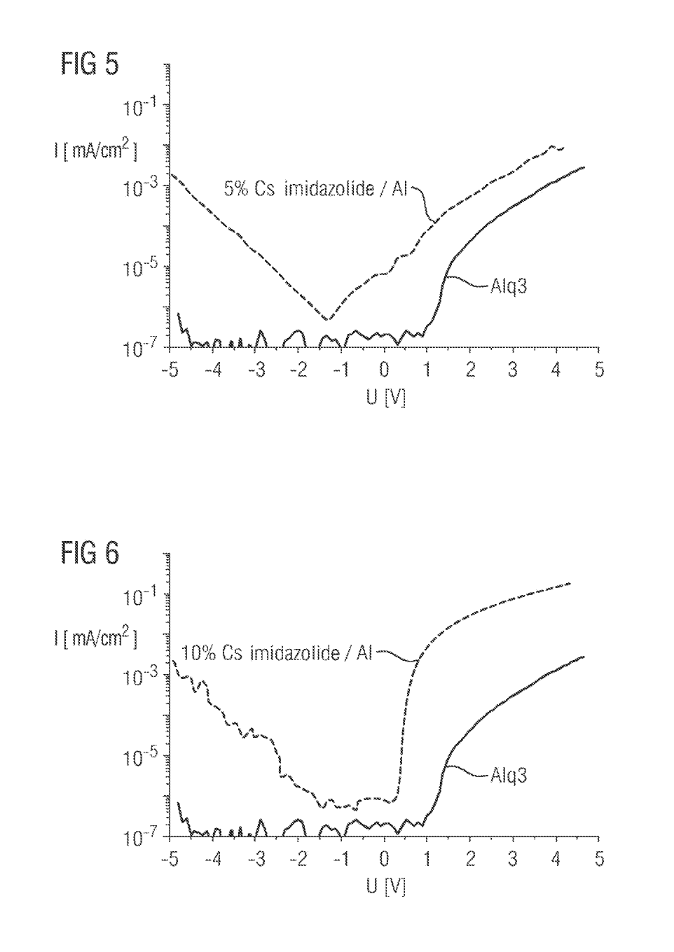

FIG. 5 the IV characteristic of a pure Alq₃ layer and of an Alq₃ layer doped with 5% cesium imidazolide (dotted), measured with an aluminum cathode;

FIG. 6 the IV characteristic of a pure Alq₃ layer and of an Alq₃ layer doped with 10% cesium imidazolide (dotted), measured with an aluminum cathode.

The figures are discussed in the examples section below.

### EXAMPLES

### I Synthesis

### I.1 Synthesis of Sodium Imidazolide

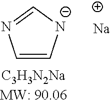

5.0 g (73.4 mmol, 1.05 eq) of imidazole and 2.8 g (69.9 mmol, 1 eq) of NaOH were introduced into a round-bottom flask and the flask was sealed with a septum. To prevent an elevated pressure, the septum was punctured with a needle. The mixture was heated to 95° C. for 72 h. A yellow solution formed and, after subsequent cooling to room temperature, 30 mL of THF were added in order to remove the excess of imidazole. The biphasic mixture was stirred at room temperature for 15 minutes, the THF was decanted off and the remaining solvent and the water which forms during the reaction were removed by means of reduced pressure. A pale yellow, solid crude product was obtained in quantitative yield (6.3 g, 69.9 mmol). ¹H NMR (400 MHz, DMSO-d6): δ 7.06 (t, J=0.8 Hz, 1H, NCHN), 6.65 (d, J=0.8 Hz, 2H, NCHCHN) ppm. ¹³C NMR (100 MHz, DMSO-d6): δ 142.6 (NCN), 124.6 (NCCN) ppm.

### 1.2 Synthesis of Potassium Imidazolide

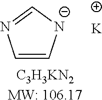

5.0 g (73.4 mmol, 1.05 eq) of imidazole and 3.9 g (69.9 mmol, 1 eq) of KOH were introduced into a round-bottom flask and the flask was sealed with a septum. To prevent an elevated pressure, the septum was punctured with a needle. The mixture was heated to 95° C. overnight. A yellow solution of high viscosity formed and, after subsequent cooling to room temperature, 30 mL of THF were added in order to remove the excess of imidazole. The biphasic mixture was stirred at room temperature for 5 minutes, the THF was decanted off and the remaining solvent and the water which forms during the reaction were removed by means of reduced pressure. In order to obtain a dry product, the flask was heated to 180° C. under reduced pressure for 3 h. The crude product was obtained as a yellow solid in 78% yield (5.8 g, 54.6 mmol). ¹H NMR (400 MHz, DMSO-d6): δ 7.02 (s, 1H, NCHN), 6.62 (d, J=0.8 Hz, 2H, NCHCHN) ppm. ¹³C NMR (100 MHz, DMSO-d6): δ 142.5 (NCN), 124.6 (NCH₃) ppm.

### I.3 Synthesis of Cesium Imidazolide

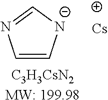

4.47 g (65.7 mmol, 1.05 eq) of imidazole and 10.5 g (62.5 mmol, 1 eq) of CsOH*H₂O were introduced into a round-bottom flask and the flask was sealed. The mixture was heated to 95° C. overnight. The heating melted the imidazole and a yellow liquid was obtained. After subsequent cooling to room temperature, 20 mL of THF were added in order to remove the excess of imidazole. The biphasic mixture was stirred at room temperature for 2 h, the THF was decanted off and the remaining solvent and the water which forms during the reaction were removed by means of reduced pressure. In order to obtain a dry product, the flask was heated to 100° C. under reduced pressure for 3 h. The crude product was obtained with a yield of 91% as a yellow solid (11.9 g, 59.5 mmol). 5.0 g of the crude product were introduced into a sublimation tube with recesses and brought to high vacuum (˜5*10⁻⁶ mbar). The tube was then heated gradually in an oven. The material melted at about 160° C. The temperature was increased further until the product began to distill over at about 410° C. After subsequent cooling to room temperature, the pure white product (˜3.5 g) was collected in an argon-filled glovebox. A small proportion of a black residue at the base of the tube was discarded. The distillation was repeated with 2.5 g of the pre-distilled material for further purification. 1.85 g of pure crystallized product were obtained. ¹H NMR (400 MHz, DMSO-d6): δ 6.96 (s, 1H, NCHN), 6.58 (d, J=0.8 Hz, 2H, NCHCHN) ppm. ¹³C NMR (100 MHz, DMSO-d6): δ 143.0 (NCN), 124.9 (NCCN) ppm.

### II. Production of the Components

II.1 SMB-013 with Cesium Imidazolide and Calcium Cathode

The reference constructed was a majority charge carrier component with the following component architecture:
glass substrate
ITO (indium tin oxide) as anode
200 nm of SMB-013
calcium as cathode
outer aluminum layer (for protection of the reactive calcium cathode)

Two components each having 15 pixels and a pixel area of 4 mm² were produced (FIG. 1, solid characteristic line).

In order to demonstrate the doping effect, a majority charge carrier component with the following component architecture was constructed:
glass substrate
ITO (indium tin oxide) as anode
200 nm of ETM-036 doped with 10% cesium imidazolide
calcium as cathode
outer aluminum layer (for protection of the reactive calcium cathode)

Two components each having 15 pixels and a pixel area of 4 mm² were produced (FIG. 1, dotted characteristic line).

It is shown that the doping with the n-dopants of the invention has an effect on the IV characteristic. The current density rises significantly in the doped layer above and below 0 V, while a typical diode characteristic is observed for the intrinsic (undoped) layer (solid characteristic line), in which a distinct overvoltage (built-in voltage) is necessary before there is a rise in the current density. Moreover, for the layer with purely intrinsic conductivity, this is the case only for positive voltages, whereas the doped layer shows elevated current densities even for negative voltages and enables efficient injection of electrons from the anode (ITO) as well.

II.2 SMB-013 with Cesium Imidazolide and Aluminum Cathode

The reference constructed was a majority charge carrier component with the following component architecture:
glass substrate
ITO (indium tin oxide) as anode
200 nm of SMB-013
aluminum as cathode

Two components each having 15 pixels and a pixel area of 4 mm² were produced (FIG. 2, solid characteristic line).

In order to demonstrate the doping effect, a majority charge carrier component with the following component architecture was constructed:
glass substrate
ITO (indium tin oxide) as anode
200 nm of ETM-036 doped with 10% cesium imidazolide
aluminum as cathode

Two components each having 15 pixels and a pixel area of 4 mm² were produced (FIG. 2, dotted characteristic line).

It is shown that the doping of the invention has an effect on the IV characteristic. The current density rises significantly in the doped layer above and below 0 V, while a typical diode characteristic is observed for the intrinsic (undoped) layer (solid characteristic line), in which a distinct overvoltage (built-in voltage) is necessary before there is a rise in the current density. Moreover, for the layer with intrinsic conductivity, this is the case only for positive voltages, whereas the doped layer shows elevated current densities even for negative voltages and enables efficient injection of electrons from the anode (ITO) as well. With the aluminum cathode, electron injection is made much more difficult by contrast with the component having a calcium cathode (example 4), since the work function of aluminum is much higher. In general, therefore, only very strong dopants enable injection of electrons from aluminum cathodes. If there is a strong doping effect, the injection of charge carriers will, however, be independent of the work function of the electrode.

II.3 Alq₃ with Cesium Imidazolide (5%+10%) and Calcium Cathode

The reference constructed was a majority charge carrier component with the following component architecture:
glass substrate
ITO (indium tin oxide) as anode
200 nm of Alq₃
calcium as cathode
outer aluminum layer (for protection of the reactive calcium cathode)

Two components each having 15 pixels and a pixel area of 4 mm² were produced (FIG. 3 and FIG. 4, solid characteristic line).

In order to demonstrate the doping effect, a majority charge carrier component with the following component architecture was constructed:
glass substrate
ITO (indium tin oxide) as anode
200 nm of Alq₃ doped with 5% (FIG. 3) or 10% (FIG. 4) cesium imidazolide
calcium as cathode
outer aluminum layer (for protection of the reactive calcium cathode)

Two components each having 15 pixels and a pixel area of 4 mm² were produced (FIG. 3 and FIG. 4, dotted characteristic line).

It is shown that the doping of the invention has an effect on the IV characteristic. The current density rises significantly in the doped layer above and below 0 V, while a typical diode characteristic is observed for the intrinsic (undoped) layer (solid characteristic line), in which a distinct overvoltage (built-in voltage) is necessary before there is a rise in the current density. Moreover, in the case of the intrinsic layer, this is the case only for positive voltages, whereas the doped layer shows elevated current densities even for negative voltages and enables efficient injection of electrons from the anode (ITO) as well.

II.4 Alq₃ with Cesium Imidazolide (5%+10%) and Aluminum Cathode

The reference constructed was a majority charge carrier component with the following component architecture:
glass substrate
ITO (indium tin oxide) as anode
200 nm of Alq₃
aluminum as cathode

Two components each having 15 pixels and a pixel area of 4 mm² were produced (FIG. 5 and FIG. 6, solid characteristic line).

In order to demonstrate the doping effect, a majority charge carrier component with the following component architecture was constructed:
glass substrate
ITO (indium tin oxide) as anode
200 nm of Alq₃ doped with 5% (FIG. 3) or 10% (FIG. 4) cesium imidazolide
aluminum as cathode

Two lots of two components each having 15 pixels and a pixel area of 4 mm² were produced (FIG. 5 and FIG. 6, dotted characteristic line).

It is shown that the doping has an effect on the IV characteristic. The current density rises significantly in the doped layer above and below 0 V, while a typical diode characteristic is observed for the intrinsic (undoped) layer (solid characteristic line), in which a distinct overvoltage (built-in voltage) is necessary before there is a rise in the current density. Moreover, in the case of the intrinsic layer, this is the case only for positive voltages, whereas the doped layer shows elevated current densities even for negative voltages and enables efficient injection of electrons from the anode (ITO) as well. With aluminum as cathode, electron injection is made much more difficult by contrast with the component having a calcium cathode (example II.3), since the work function of aluminum is much higher. In this case too, an improvement is achieved. In general, only very strong dopants enable injection of electrons from the aluminum cathode. If there is a strong doping effect, the injection of charge carriers will, however, be independent of the work function of the electrode.

Although the invention has been illustrated and described in detail by the preferred working examples, the invention is not restricted by the examples disclosed, and other variations can be derived therefrom by the person skilled in the art without leaving the scope of protection of the invention.

What is claimed is:

1. An n-dopant for increasing the electrical conductivity of organic electrical layers, the n dopant comprising heterocyclic alkali metal salts of the following formula 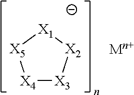
wherein
X₁-X₅ are independently selected from the group consisting of —CH₂—, —CHR—, —CR₂—, —C(═O)—, —(C═S)—, —(C═CR₂)—, —C(CR)—, ═CH—, ═CR—, —NH—, —NR—, ═N—, —O—, —S—, —Se—, —P(H)—, —P(R)—, —N⁻—, ═C⁻—, —CH⁻—, —CR⁻—, and —P⁻—, wherein at least one of X₁-X₅ provides a heteroatom in the five-membered ring and the ring has a formal negative charge;
R is independently selected from the group consisting of —H, -D, halogen, —CN, —NO₂, —OH, amine, ether, thioether, ester, amide, C1-C50 alkyl, cycloalkyl, acryloyl, vinyl, allyl, aromatics, fused aromatics, and heteroaromatics;
M=alkali metal or alkaline earth metal; and
n=1 or 2.

2. An n-dopant as claimed in claim 1, wherein the at least one heteroatom in the five-membered ring is a nitrogen atom.

3. An n-dopant as claimed in claim 2, further comprising a second nitrogen atom in the five-membered ring.

4. An n-dopant as claimed in claim 1, wherein the metal M is selected from the group consisting of Li, Na, K, Rb and Cs.

5. An n-dopant as claimed in claim 1, wherein the metal comprises Rb or Cs.

6. An n-dopant as claimed in claim 1, wherein the metal comprises Cs.

7. An n-dopant as claimed in claim 1, wherein the n-dopant has a molecular weight of about ≥65 g/mol and about ≤2000 g/mol.

8. An organic electron-conducting layer comprising an electron transport material and an n-dopant, wherein the n-dopant comprises a heterocyclic alkali metal salt of the following formula 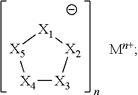
wherein
X₁-X₅ are independently selected from the group consisting of —CH₂—, —CHR—, —CR₂—, —C(═O)—, —(C═S)—, —(C═CR₂)—, —C(CR)—, ═CH—, ═CR—, —NH—, —NR—, ═N—, —O—, —S—, —Se—, —P(H)—, —P(R)—, —N⁻—, ═C⁻—, —CH⁻—, —CR⁻—, and —P⁻—, wherein at least one of X₁-X₅ provides a heteroatom in the five-membered ring and the ring has a formal negative charge;
R is independently selected from the group consisting of —H, -D, halogen, —CN, —NO₂, —OH, amine, ether, thioether, ester, amide, C1-C50 alkyl, cycloalkyl, acryloyl, vinyl, allyl, aromatics, fused aromatics, and heteroaromatics;
M=alkali metal or alkaline earth metal; and
n=1 or 2.

9. The organic electron-conducting layer as claimed in claim 8, wherein the n-dopant is present in the organic electrical layer in a layer thickness concentration of about ≥0.01% to about ≤35%.

10. The organic electron-conducting layer as claimed in claim 8, wherein the n-dopant is present in the organic electrical layer in a layer thickness concentration of about ≥70% to about ≤100%.

11. A process for producing an organic electrical layer, the process comprising depositing an n-dopant within a layer together with at least one electron transport material, wherein the n-dopant comprises a heterocyclic alkali metal salt of the following formula 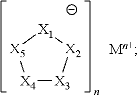
wherein
X₁-X₅ are independently selected from the group consisting of —CH₂—, —CHR—, —CR₂—, —C(═O)—, —(C═S)—, —(C═CR₂)—, —C(CR)—, ═CH—, ═CR—, —NH—, —NR—, ═N—, —O—, —S—, —Se—, —P(H)—, —P(R)—, —N⁻—, ═C⁻—, —CH⁻—, —CR⁻—, and —P⁻—, wherein at least one of X₁-X₅ provides a heteroatom in the five-membered ring and the ring has a formal negative charge;
R is independently selected from the group consisting of —H, -D, halogen, —CN, —NO₂, —OH, amine, ether, thioether, ester, amide, C1-C50 alkyl, cycloalkyl, acryloyl, vinyl, allyl, aromatics, fused aromatics, and heteroaromatics;
M=alkali metal or alkaline earth metal; and
n=1 or 2.

12. The process as claimed in claim 11, wherein the n-dopant is deposited within a layer without an electron transport material.

13. The process as claimed in claim 11, wherein the deposition is effected via a sublimation operation with a sublimation temperature of about ≥120° C. to about ≤600° C. and at a pressure of about 1*10⁻⁵ to about 1*10⁻⁹ mbar.

14. An organic electrical component comprising an n-conducting organic electrical layer comprising an n-dopant within a layer together with at least one electron transport material, wherein the n-dopant comprises a heterocyclic alkali metal salt of the following formula 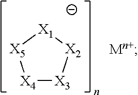
wherein
X₁-X₅ are independently selected from the group consisting of —CH₂—, —CHR—, —CR₂—, —C(═O)—, —(C═S)—, —(C═CR₂)—, —C(CR)—, ═CH—, ═CR—, —NH—, —NR—, ═N—, —O—, —S—, —Se—, —P(H)—, —P(R)—, —N⁻—, ═C⁻—, —CH⁻—, —CR⁻—, and —P⁻—, wherein at least one of X₁-X₅ provides a heteroatom in the five-membered ring and the ring has a formal negative charge;
R is independently selected from the group consisting of —H, -D, halogen, —CN, —NO₂, —OH, amine, ether, thioether, ester, amide, C1-C50 alkyl, cycloalkyl, acryloyl, vinyl, allyl, aromatics, fused aromatics, and heteroaromatics;
M=alkali metal or alkaline earth metal; and
n=1 or 2.

15. The organic electrical component as claimed in claim 14, wherein the component is selected from the group consisting of organic photodiodes, solar cells, bipolar transistors, field-effect transistors, and organic light-emitting diodes.
